(19) United States
(12) Patent Application Publication
(10) Pub. No.: US 2025/0219525 A1
(43) Pub. Date: Jul. 3, 2025

(54) RESISTOR DETECTION CIRCUIT

(71) Applicant: TEXAS INSTRUMENTS INCORPORATED, Dallas, TX (US)

(72) Inventors: Yong XIE, Plano, TX (US); Fei YANG, Plano, TX (US); Nathan SCHEMM, Rowlett, TX (US); Anant Shankar KAMATH, Bangalore (IN)

(21) Appl. No.: 18/932,709

(22) Filed: Oct. 31, 2024

Related U.S. Application Data
(60) Provisional application No. 63/616,875, filed on Jan. 2, 2024.

(51) Int. Cl. H02M 1/08; H02M 3/155; H03K 5/01

(52) U.S. Cl. CPC H02M 1/08; H02M 3/155; H03K 5/01

(57) ABSTRACT

A circuit includes a current source, a first switch, a second switch, a sample and hold circuit, and an analog-to-digital converter (ADC). The current source has a current input coupled to an input terminal configured for resistor connection, a first current output, and a second current output. The first switch has a first terminal coupled to the first current output, and a second terminal. The second switch has a first terminal coupled to the second current output, and a second terminal. The sample and hold circuit has an input coupled to the second terminal of the first switch and the second terminal of the second switch, and an output. The ADC has an input coupled to the output of the sample and hold circuit.

### CROSS-REFERENCE TO RELATED APPLICATIONS

This application claims priority to U.S. Provisional Application No. 63/616,875, filed Jan. 2, 2024, entitled “Detecting Multiple Resistors on the Same Pin,” which is hereby incorporated by reference in its entirety.

### BACKGROUND

Power transistors are used in switching power supplies and a wide variety of other applications. In order to reduce switching losses in power transistors, the power transistors must be switched on and off very rapidly. Because the power transistor's control terminal may present significant capacitance, a gate driver circuit may be employed to buffer an input signal and drive the power transistor's control terminal. The gate driver circuit receives a low-power input signal and buffers the input signal to produce a high-current signal that quickly charges or discharges the input capacitance of the power transistor. Examples of power transistors with which a gate driver circuit may be employed include insulated gate bipolar transistors, metal oxide semiconductor field-effect-transistors, and gallium nitride transistors.

### SUMMARY

In one example, a circuit includes a voltage controlled current source, a first switch, a second switch, a sample and hold circuit, and an analog-to-digital converter (ADC). The current source has an input coupled to an input terminal configured for resistor connection, a first current output, and a second current output. The first switch has a first terminal coupled to the first current output, and a second terminal. The second switch has a first terminal coupled to the second current output, and a second terminal. The sample and hold circuit has an input coupled to the second terminal of the first switch and the second terminal of the second switch, and an output. The ADC has an input coupled to the output of the sample and hold circuit.

In another example, a circuit includes a transistor, a driver circuit, and a slew rate detection circuit. The transistor has a control terminal. The driver circuit has an output coupled to the control terminal, and a slew control input. The slew rate detection circuit has a slew control output coupled to the slew control input, and a slew setting terminal. The slew rate detection circuit is configured to determine a first slew rate based on a first current at the slew setting terminal, and provide a first slew rate control signal, representing the first slew rate, at the slew control output, and determine a second slew rate based on a second current at the slew setting terminal, and provide a second slew rate control signal, representing the second slew rate, at the slew control output.

In a further example, a switch-mode converter includes a transistor, a control circuit, a first resistor, a second resistor, and a capacitor. The transistor has a control terminal. The control circuit has a slew setting terminal. The first resistor is coupled between the slew setting terminal and a reference terminal. The second resistor and the capacitor are coupled in series between the slew setting terminal and the reference terminal. The control circuit includes a driver circuit and a slew rate detection circuit. The driver circuit has an output coupled to the control terminal of the transistor, and a slew control input. The slew rate detection circuit has a slew control output coupled to the slew control input, and an input coupled to the slew setting terminal. The slew rate detection circuit is configured to determine a first slew rate based on a first current at the slew setting terminal, and provide a first slew rate control signal, representing the first slew rate, at the slew control output, and determine a second slew rate based on a second current at the slew setting terminal, and provide a second slew rate control signal, representing the second slew rate, at the slew control output.

### BRIEF DESCRIPTION OF THE DRAWINGS

FIG. 1 is a block diagram of an example gate driver circuit that includes slew rate detection to set rise and fall times of a gate driver.

FIG. 2 is schematic diagram of an example slew rate detection circuit suitable for use in the gate driver circuit of FIG. 1.

FIG. 3 is a graph of example signals in the slew rate detection circuit of FIG. 2.

FIG. 4 is a block diagram of an example switch-mode converter circuit that includes the gate driver circuit of FIG. 1.

### DETAILED DESCRIPTION

Modern power transistors, such as gallium nitride (GaN) power field effect transistors, can be switched at high slew rates to reduce switching losses. However, in systems with larger parasitic inductances or capacitances, the high slew rates cause an increase in switching transients and electromagnetic interference (EMI). Slew rate selection capability allows switching loss and EMI to be tuned as needed for a particular application. In some examples, independent control of transistor turn-on slew rate and transistor turn-off slew rate is desirable to adjust EMI and switching loss. If the driver circuitry controlling a power transistor is provided on an integrated circuit, resistors coupled to terminals of the integrated circuit can be used to set the slew rates. However, using multiple terminals of an integrated circuit to set the slew rates can necessitate an undesirable increase in package size and/or cost. The circuits disclosed herein allow multiple resistors coupled to a single terminal of an integrated circuit to be used to set operational parameters, such as transistor turn-on and turn-off slew rates.

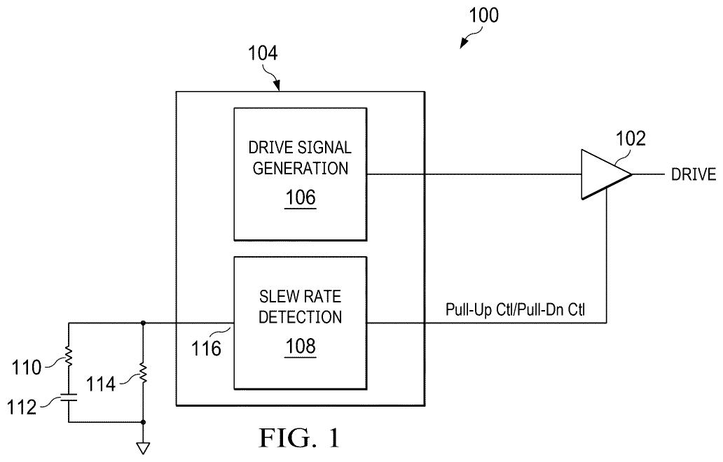

FIG. 1 is a block diagram of an example gate driver circuit 100. The gate driver circuit 100 includes a driver 102, and a control circuit 104. The driver 102 and the control circuit 104 may be provided on the same integrated circuit. The driver 102 has a signal input coupled to the control circuit 104 for receipt of a transistor control signal, and an output for providing a drive signal (Drive) to a transistor. The driver 102 includes circuitry that provides current to the drive signal to set the turn-on and turn-off rate of the transistor. The driver 102 has a slew control input that is coupled to the control circuit 104 for receipt of one or more slew rate control signals. The driver 102 can set the turn-on current and the turn-off current of the drive signal based on the slew rate control signals to control EMI and switching loss. For example, slew rate may be reduced to reduce EMI while potentially increasing switching loss, or slew rate may be increased to reduce switching loss while potentially increasing EMI.

The control circuit 104 includes a drive signal generation circuit 106 and a slew rate detection circuit 108. The drive signal generation circuit 106 has an output at which the drive signal generation circuit 106 provides the transistor control signal to the driver 102. The output of the drive signal generation circuit 106 is coupled to the signal input of the driver 102. The drive signal generation circuit 106 may include pulse width modulation circuitry or other circuits to generate the transistor control signal.

The slew rate detection circuit 108 provides the slew rate control signals to the driver 102. The slew rate detection circuit 108 includes an output coupled to the slew control input of the driver 102. The slew rate control signals include a turn-on slew rate control signal (Pull-Up Ctl) for setting the current provided by the driver 102 to turn on a transistor, and a turn-off slew rate control signal (Pull-Dn Ctl) for setting the current drawn by the driver 102 to turn off the transistor. The slew rate detection circuit 108 has a slew setting terminal 116 at which slew control information is provided to the slew rate detection circuit 108. The slew control information is provided by a resistor 110, a resistor 114, and a capacitor 112 that are coupled to the slew setting terminal 116. The slew setting terminal 116 may be a single pin or terminal (e.g., an input or input/output terminal) of an integrated circuit including the slew rate detection circuit 108.

The resistor 110, the resistor 114, and the capacitor 112 can be provided external to the gate driver circuit 100 to allow the values of the resistor 110 and the resistor 114 to be selected, where the resistance values of the resistor 110 and the resistor 114 determine the values of the slew rate control signals, and the capacitance value of the capacitor 112 is selected to provide a reasonable short time constant. The resistance of the resistor 114 may determine the value of Pull-Up Ctl, and the resistance of the resistor 110 may determine the value of Pull-Dn Ctl. Accordingly, the slew rate detection circuit 108 controls the turn-on and turn-of currents of the drive signal (and the slew rates of a transistor controlled by the drive signal) based on the resistance of the resistor 110 and the resistor 114.

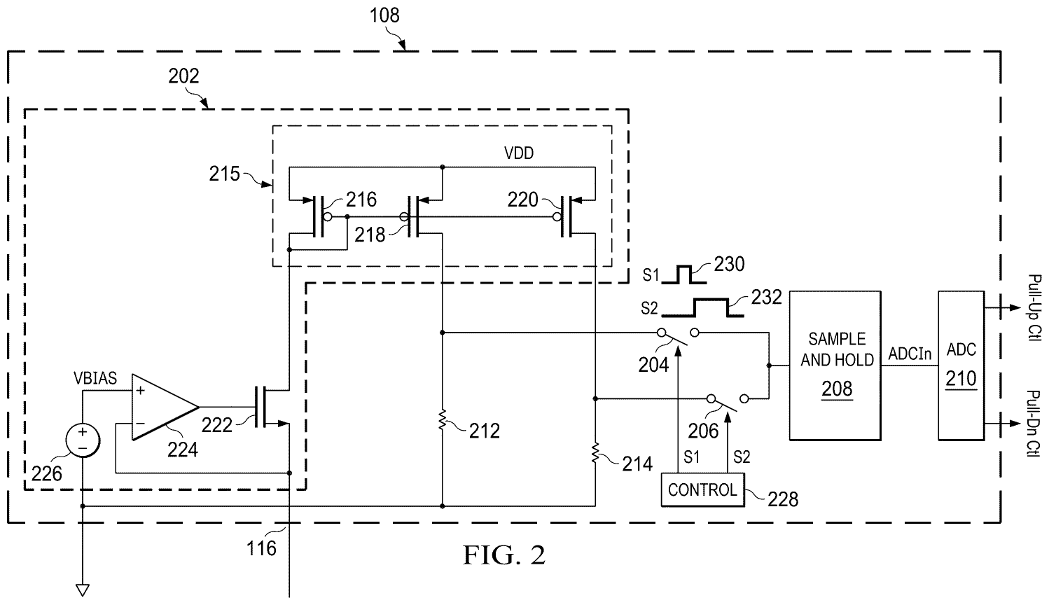

FIG. 2 is schematic diagram of an example slew rate detection circuit 108. The slew rate detection circuit 108 includes a voltage controlled current source 202, a switch 204, a switch 206, a sample and hold circuit 208, an analog-to-digital converter (ADC) 210, a resistor 212, a resistor 214, and a control circuit 228. The voltage controlled current source 202 has an input coupled to the slew setting terminal 116, a first output coupled to the resistor 212, and a second output coupled to the resistor 214. The resistances of the resistors 212 and 214 may be selected to produce a voltage suitable for analog-to-digital conversion with the currents provided at the first and second outputs the voltage controlled current source 202. The voltage controlled current source 202 includes a current mirror circuit 215, a transistor 222, an amplifier 224, and a voltage source 226. The current mirror circuit 215 includes transistors 216, 218, and 220. The transistors 216, 218, and 220 may be p-channel field effect transistors (PFETs). A first terminal (e.g., source) of the transistor 216 is coupled to a power terminal (VDD), and a second terminal (e.g., drain) of the transistor 216 is coupled to a control terminal (e.g., gate) of the transistor 216. The transistor 218 has a first terminal (e.g., source) coupled to the first terminal of the transistor 216, a second terminal (e.g., drain) coupled to the resistor 212, and a control terminal (e.g., gate) coupled to the control terminal of the transistor 216. The transistor 220 has a first terminal (e.g., source) coupled to the first terminal of the transistor 216, a second terminal (e.g., drain) coupled to the resistor 214, and a control terminal (e.g., gate) coupled to the control terminal of the transistor 216. The transistor 218 and the transistor 220 may be scaled replicas of the transistor 216 in some examples of the current mirror circuit 215.

The transistor 222 is coupled between the current mirror circuit 215 and the slew setting terminal 116. The transistor 222 may be an n-channel field effect transistor (NFET). The transistor 222 includes a first terminal (e.g., drain) coupled to the second terminal of the transistor 216, a second terminal (e.g., source) coupled to the slew setting terminal 116, and a control terminal (e.g., gate) coupled to the amplifier 224. The amplifier 224 has a first input (e.g., non-inverting input) coupled to the voltage source 226, a second input (e.g., inverting input) coupled to the second terminal of the transistor 222, and an output coupled to the control terminal of the transistor 222. The voltage source 226 has an output coupled to the first input of the amplifier 224, and reference terminal coupled to a ground terminal. The voltage source 226 provides a reference voltage at the output of the voltage source 226. The voltage source 226 may be a band-gap circuit or other voltage source. The amplifier 224 controls the transistor 222 to set the voltage at the slew setting terminal 116 equal to the reference voltage provided by the voltage source 226.

The resistor 212 has a first terminal coupled to the second terminal of the transistor 218, and a second terminal coupled to the reference terminal. The resistor 214 has a first terminal coupled to the second terminal of the transistor 220 and a second terminal coupled to the reference terminal. The current flowing through the transistor 216 to the slew setting terminal 116 is mirrored by the transistor 218 and the transistor 220. Voltages developed across the resistor 212 and the resistor 214 are representative of the currents flowing through the resistor 212 and the resistor 214. These voltages are measured to estimate the values of the resistor 110 and the resistor 114 coupled to the slew setting terminal 116 (or the currents flowing therethrough).

The switch 204 and the switch 206 switch the voltages across the resistor 212 and the resistor 214 to the sample and hold circuit 208. The switch 204 has a first terminal coupled to the first terminal of the resistor 212, and a second terminal coupled to an input of the sample and hold circuit 208. A control input of the switch 204 is coupled to a first output of the control circuit 228. The switch 206 has a first terminal coupled to the first terminal of the resistor 214, and a second terminal coupled to the input of the sample and hold circuit 208. A control input of the switch 206 is coupled to a second output of the control circuit 228. The control circuit 228 generates switch control signals S1 and S2 that are provided at the first and second outputs of the control circuit 228. S1 controls the switch 204, and S2 controls the switch 206. Examples of the switch control pulses 230 and 232 provided on S1 and S2 are shown in FIG. 2. With S1 having a logic high state, the switch 204 is closed, and the voltage across the resistor 212 is provided at the input of the sample and hold circuit 208. With S2 having a logic high state, the switch 206 is closed, and the voltage across the resistor 214 is provided at the input of the sample and hold circuit 208. The control circuit 228 may provide the switch control pulse 230 on S1 at power-up of the slew rate detection circuit 108 to enable measurement of the voltage across the resistor 212. After the control circuit 228 resets S1 to a logic low, the control circuit 228 provides the switch control pulse 232 on S2 to enable measurement of the voltage across the resistor 214.

The sample and hold circuit 208 samples the voltages present across the resistor 212 and resistor 214, and holds the sampled voltages for digitization. The sample and hold circuit 208 samples the voltage across the resistor 212 during the switch control pulse 230, and samples the voltage across the resistor 214 during the switch control pulse 232. An output of the sample and hold circuit 208 is coupled to an input of the ADC 210. The sample voltage held by the sample and hold circuit 208 is provided at the output of the sample and hold circuit 208 as a signal ADCIn. The ADC 210 converts ADCIn to digital values. The digital value (e.g., a slew rate value) generated by the ADC 210 based on the sampled voltage across the switch 204 may be Pull-Dn Ctl, and the digital value (e.g., a slew rate value) generated by the ADC 210 based on the sampled voltage across the switch 206 may be Pull-Up Ctl. The ADC 210 may be a successive approximation converter in some examples of the 108, but other ADC conversion technologies may also be used. The ADC 210 may be a four-bit converter in some examples of the 108. The ADC 210 may provide a different number of output bits in other examples of the 108.

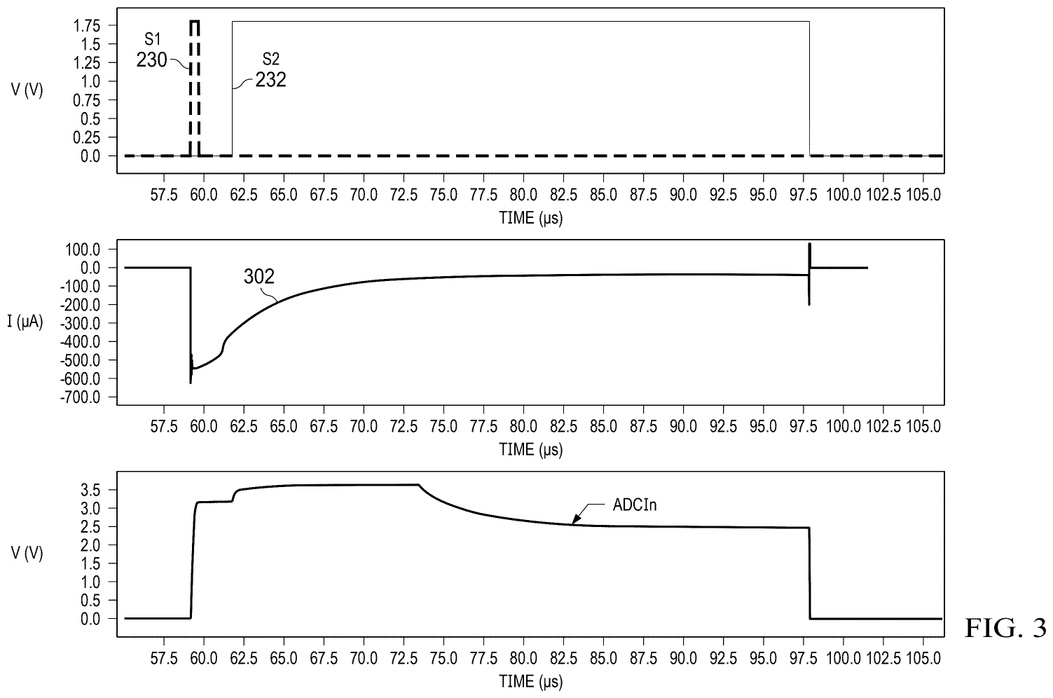

FIG. 3 is a graph of example signals in the slew rate detection circuit 108. The switch control signals S1 and S2, the current 302 flowing through the slew setting terminal 116, and the input voltage ADCIn provided to the ADC 210 are shown in FIG. 3. At power up of the slew rate detection circuit 108, the capacitor 112 is not yet charged and current (e.g., 500 micro-amperes) flows from the voltage controlled current source 202 through the resistor 110 and the resistor 114. If the resistor 110 is significantly smaller in resistance than the resistor 114, then most of the current flows through the resistor 110. The current flowing from the voltage controlled current source 202 through the slew setting terminal 116 is mirrored by the transistors 218 and 220. The control circuit 228 sets S1 to a logic high (during the switch control pulse 230), the switch 204 is closed, and the sample and hold circuit 208 samples the voltage across the resistor 212. The switch control pulse 230 may be relatively narrow (e.g., 500 nanoseconds in width). When the control circuit 228 switches S1 to a logic low (at the end of the switch control pulse 230), the ADC 210 digitizes the sampled voltage (ADCIn) to produce Pull-Dn Ctl

After the end of the switch control pulse 230 (e.g., a few micro-seconds after), the control circuit 228 sets S2 to a logic high (during the switch control pulse 232), the switch 206 is closed, and the sample and hold circuit 208 samples the voltage across the resistor 214. The switch control pulse 232 may be relatively broad (e.g., 35 microseconds in width). By the end of the switch control pulse 232, the capacitor 112 is charged, and current is flowing only through the resistor 114. Before the control circuit 228 switches S2 to a logic low (at the end of the switch control pulse 232), the ADC 210 digitizes the sampled voltage (ADCIn) to produce Pull-Up Ctl.

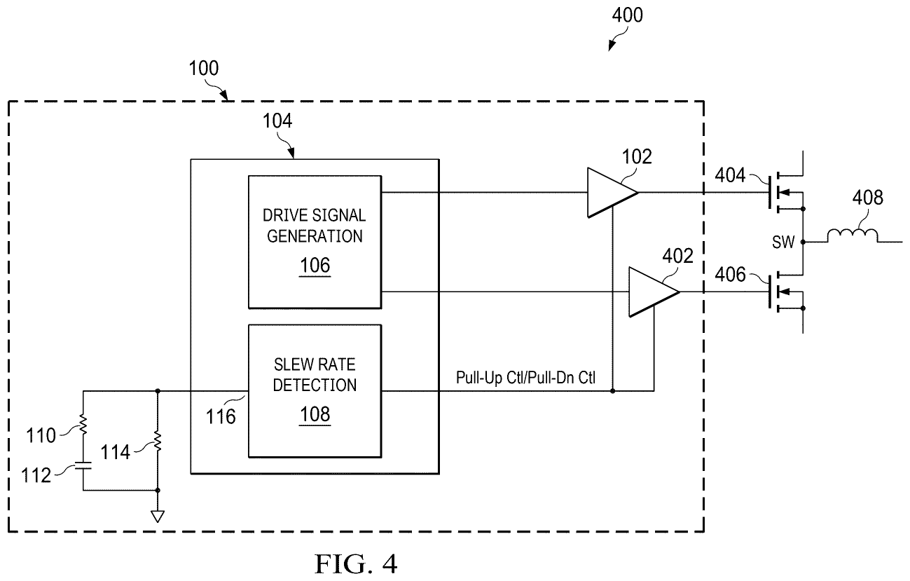

FIG. 4 is a block diagram of an example switch-mode converter circuit 400. The switch-mode converter circuit 400 may be a power factor correction circuit, an inverter circuit, a DC-DC converter, or other switch-mode converter circuit. The switch-mode converter circuit 400 includes an example of the gate driver circuit 100 with drivers 102 and 402. The output of the driver 102 is coupled to the control terminal (e.g., gate) of a transistor 404, and the output of the driver 402 is coupled to the control terminal (e.g., gate) of a transistor 406. The transistor 404 and the transistor 406 may be n-channel metal oxide semiconductor, gallium nitride, silicon carbide, or other types of transistors. A first terminal (e.g., drain) of the transistor 404 may be coupled to an input voltage terminal in some examples or coupled to an output voltage terminal in other examples. A second terminal (e.g., source) of the transistor 404 is coupled to a first terminal (e.g., drain) of the transistor 406 at a switching terminal (SW). A second terminal of the transistor 406 may be coupled to an input voltage terminal in some examples or coupled to an output voltage terminal in other examples. A first terminal of an inductor 408 is also coupled to the switching terminal. A second terminal of the inductor 408 may be coupled to variety of components based on the application in which the switch-mode converter circuit 400 is used.

The gate driver circuit 100 includes the slew rate detection circuit 108. The slew rate detection circuit 108 controls the pull-up and pull-down currents provided by the driver 102 and the driver 402 based on values of the resistor 110 and resistor 114 coupled to the slew setting terminal 116. Accordingly, the switch-mode converter circuit 400 allows for control of EMI versus switching loss by selection of the resistors 110 and 114, where the resistors 110 and 114 are coupled to a single terminal of an integrated circuit that includes the slew rate detection circuit 108.

While the use of multiple resistors coupled to a single terminal of an integrated circuit has been described herein with respect to slew rate control, the slew rate detection circuit 108 as described herein may be more generally described as a resistor detection circuit. Such a resistor detection circuit can be used to determine the resistance values of any number of resistors coupled to a single terminal of an integrated circuit, where the resistance values can provide selection information for controlling a wide variety of functions in the integrated circuit.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET)) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
a current source having a first current input coupled to an input terminal configured for resistor connection, a first current output, and a second current output;
a first switch having a first terminal coupled to the first current output, and a second terminal;
a second switch having a first terminal coupled to the second current output, and a second terminal;
a sample and hold circuit having an input coupled to the second terminal of the first switch and the second terminal of the second switch, and an output; and
an analog-to-digital converter (ADC) having an input coupled to the output of the sample and hold circuit.

2. The circuit of claim 1, further comprising a resistor coupled between the first terminal of the first switch and a reference terminal.

3. The circuit of claim 1, further comprising a resistor coupled between the first terminal of the second switch and a reference terminal.

4. The circuit of claim 1, wherein”
the first switch has a first control input, and the second switch has a second control input; and
the circuit includes a control circuit having a first control output coupled to the first control input, and second control output coupled to the second control input.

5. The circuit of claim 4, wherein:
the control circuit is configured to:
provide a first switch control pulse at the first control output to close the first switch, and provide a second switch control pulse at the second control output to close the second switch; and
the first switch control pulse precedes the second switch control pulse.

6. The circuit of claim 5, wherein the ADC is configured to:
provide a first value representative of current flow through a first resistor and a second resistor coupled to the input terminal responsive to the first switch control pulse; and
provide a second value representative of current flow through the first resistor responsive to the second switch control pulse.

7. The circuit of claim 1, wherein the current source includes”
a first transistor having a first terminal, a second terminal coupled to the input terminal, and a control terminal coupled to the second terminal of the first transistor;
a second transistor having a first terminal coupled to the first terminal of the first transistor, a second terminal coupled to the first terminal of the first switch, and a control terminal coupled to the control terminal of the first transistor; and
a third transistor having a first terminal coupled to the first terminal of the first transistor, a second terminal coupled to the first terminal of the second switch, and a control terminal coupled to the control terminal of the first transistor.

8. A circuit comprising:
a transistor having a control terminal;
a driver circuit having an output coupled to the control terminal, and a slew control input;
a slew rate detection circuit having a slew control output coupled to the slew control input, and a slew setting terminal, the slew rate detection circuit configured to:
determine a first slew rate based on a first current at the slew setting terminal, and provide a first slew rate control signal, representing the first slew rate, at the slew control output; and
determine a second slew rate based on a second current at the slew setting terminal, and provide a second slew rate control signal, representing the second slew rate, at the slew control output.

9. The circuit of claim 8, wherein:
the first current flows through a first resistor and a second resistor coupled in parallel to the slew setting terminal; and
the second current flows through the second resistor coupled to the slew setting terminal.

10. The circuit of claim 8, wherein the slew rate detection circuit includes:
a current source having a current input coupled to the slew setting terminal, a first current output, and a second current output;
a first resistor having a first terminal coupled to the first current output, and a second terminal;
a second resistor having a first terminal coupled to the second current output, and a second terminal;
a sample and hold circuit having an input coupled to the second terminal of the first resistor and the second terminal of the second resistor, and an output; and
an analog-to-digital converter (ADC) having an input coupled to the output of the sample and hold circuit.

11. The circuit of claim 10, wherein the ADC is configured to:
provide a first digital value representing a voltage across the first resistor as a first slew rate value; and
provide a second digital value representing a voltage across the second resistor as a second slew rate value.

12. The circuit of claim 10, wherein the slew rate detection circuit includes:
a first switch coupled between the first terminal of the first resistor and the input of the sample and hold circuit, the first switch having a first control input; and
a second switch coupled between the first terminal of the second resistor and the input of the sample and hold circuit, the second switch having a second control input.

13. The circuit of claim 12, wherein the slew rate detection circuit includes a control circuit having a first control output coupled to the first control input, and second control output coupled to the second control input, the control circuit configured to provide a first switch control pulse at the first control output to close the first switch, and provide a second switch control pulse at the second control output to close the second switch.

14. The circuit of claim 10, wherein the current source includes:
a current mirror circuit including:
a first transistor configured to receive an input current at the current input;
a second transistor configured to provide a second current at the first current output; and
a third transistor configured to provide a third current at the second current output.

15. A switch-mode converter, comprising:
a transistor having a control terminal;
a control circuit having a slew setting terminal, the control circuit including:
a driver circuit having an output coupled to the control terminal of the transistor, and a slew control input;
a slew rate detection circuit having a slew control output coupled to the slew control input, and an input coupled to the slew setting terminal, the slew rate detection circuit configured to:
determine a first slew rate based on a first current at the slew setting terminal, and provide a first slew rate control signal, representing the first slew rate, at the slew control output; and
determine a second slew rate based on a second current at the slew setting terminal, and provide a second slew rate control signal, representing the second slew rate, at the slew control output;
a first resistor coupled between the slew setting terminal and a reference terminal; and
a second resistor and a capacitor coupled in series between the slew setting terminal and the reference terminal.

16. The switch-mode converter of claim 15, wherein the slew rate detection circuit includes:
a current source having a current input coupled to the slew setting terminal, a first current output, and a second current output;
a first switch having a first terminal coupled to the first current output, and a second terminal;
a second switch having a first terminal coupled to the second current output, and a second terminal;
a sample and hold circuit having an input coupled to the second terminal of the first switch and the second terminal of the second switch, and an output; and
an analog-to-digital converter (ADC) having an input coupled to the output of the sample and hold circuit.

17. The switch-mode converter of claim 16, further comprising:
a third resistor coupled between the first terminal of the first switch and the reference terminal; and
a fourth resistor coupled between the first terminal of the second switch and the reference terminal.

18. The switch-mode converter of claim 17, wherein the ADC is configured to provide the first slew rate control signal based on a voltage across the third resistor, and provide a second slew rate control signal based on a voltage across the fourth resistor.

19. The switch-mode converter of claim 16, wherein:
the first switch has a first control input, and the second switch has a second control input; and
the control circuit is configured to provide a first switch control pulse at the first control input to close the first switch, and provide a second switch control pulse at the second control input to close the second switch; and
the first switch control pulse precedes the second switch control pulse.

20. The switch-mode converter of claim 16, wherein the current source includes:
a current mirror circuit including:
a first transistor configured to receive a first current at the current input;
a second transistor configured to provide a second current at the first current output; and’
a third transistor configured to provide a third current at the second current output.
